(19) United States
(12) Patent Application Publication
(10) Pub. No.: US 2002/0090742 A1
(43) Pub. Date: Jul. 11, 2002

(54) Semiconductor device and method for fabricating the same

(75) Inventors: Kenji Maruyama, Kawasaki (JP); Kazuaki Kurihara, Kawasaki (JP)

Correspondence Address: ARMSTRONG,WESTERMAN & HATTORI, LLP, 1725 K STREET, NW., SUITE 1000, WASHINGTON, DC, 20006, US

(73) Assignee: Fujitsu Limited, Kawasaki (JP)

(21) Appl. No.: 09/960,296

(22) Filed: Sep. 24, 2001

(30) Foreign Application Priority Data
Jan. 11, 2001 (JP) 2001-4150

(51) Int. Cl. H01L 21/00; H01L 29/00

(52) U.S. Cl. 438/3; 257/532

(57) ABSTRACT

A semiconductor device comprises a first electrode 32, a ferroelectric film 36 formed above the first electrode, and a second electrode 40 formed above the ferroelectric film, which further comprises intermediate layers 34, 38 formed at least one of boundary between the first electrode and the ferroelectric film, and boundary between the ferroelectric film and the second electrode and having perovskite crystal structure. The intermediate layers having perovskite crystal structure are formed between the first electrode and the ferroelectric film and between the ferroelectric film and the second electrode, whereby even in a case that base metal is used as a material of the bottom electrode and the top electrode of a ferroelectric capacitor, the ferroelectric film can have crystal structure exhibiting ferroelectricity. Base metal can be used as a material of the bottom electrode and the top electrode of the ferroelectric capacitor, which decreases costs of semiconductor devices. Materials which have been difficult to use as materials of the bottom electrode and the top electrode of a ferroelectric capacitor can be used, whereby fabrication processes can be simplified, and electric characteristics can be improved.

### CROSS-REFERENCE TO RELATED APPLICATIONS

This application is based upon and claims priority of Japanese Patent Application No. 2001-004150 filed in Jan. 11, 2001, the contents being incorporated herein by reference.

### BACKGROUND OF THE INVENTION

The present invention relates to a semiconductor device and a method for fabricating the semiconductor device, more specifically a semiconductor device including capacitors and a method for fabricating the semiconductor device.

FRAM (Ferro-electric Random Access Memory) is an nonvolatile semiconductor memory using a ferroelectric film as the dielectric of the capacitors. FRAM has rewriting speed as high as about tens of nanoseconds and has good repeatability of 1×10¹⁰ to 1×1¹² rewritable times. Furthermore, FRAM has small electric power consumption. Because of these factors, FRAM is much noted. FRAM, which can retain data when the electric power is turned off, is expected to be applied to various uses, such as memories of portable instruments, etc.

A structure of the capacitors of the FRAM will be explained with reference to FIG. 13. FIG. 13 is a conceptual view of a capacitor of the conventional FRAM.

A bottom electrode 132 is formed on a silicon substrate not shown through a silicon oxide film, etc. not shown. A ferroelectric film 136 is formed on the bottom electrode 132. An top electrode 140 is formed on the ferroelectric film 136.

The bottom electrode 132, the ferroelectric film 136 and the top electrode 140 constitute the capacitor 142 of the FRAM.

The ferroelectric film 136 of such capacitors 142 can be PZT (PbZr_{X}Ti_{1-X}O₃) film, SBT (SrBi₂Ta₂O₉) film or others.

For example, in a case of the ferroelectric film 136 of PZT, it is necessary to subject the PZT film to high-temperature thermal processing of about 600° C. to be crystallized into perovskite structure, which exhibits ferroelectricity.

Accordingly, the bottom electrode 132 and the top electrode 140 of the capacitors are formed of Pt, Ir or others, which has strong self-orientation and low reactivity.

Pt, Ir, etc. are materials which tend to be self-oriented in (111). In cases that the bottom electrode and the top electrode are formed of such materials, crystal directions of the surfaces of the bottom electrode and the top electrodes can be easily aligned. Accordingly, in such cases, crystal directions of the ferroelectric film can be easily aligned, and the ferroelectric film can have good perovskite crystal structure. Furthermore, Pt, Ir, etc. have a property that they are not easily oxidized by heat processing at high temperatures. Conventionally Pt, Ir, etc. have been used as materials of the bottom electrode 132 and the top electrode 140 of the capacitors.

However, Pt, Ir, etc. forming the bottom electrode and the top electrode are expensive noble metals, and their market prices are not constant. This has been a barrier to low costs of the semiconductor devices. Here, noble metals is opposed to base metals and generally means metals which do not easily undergo chemical changes, are not easily oxidized by heating in air and have low ionization tendency.

Materials forming the bottom electrode and the top electrode of the capacitors are restrictively limited to Pt, Ir, etc., which has been a barrier to simplification of the fabrication process, further improvement of electric characteristics, etc.

### SUMMARY OF THE INVENTION

An object of the present invention is to provide a semiconductor device and a method for fabricating the semiconductor device which can realize low costs.

Another object of the present invention is to provide a semiconductor device and a method for fabricating the semiconductor device which allow a material which has been difficult to use as a material forming the bottom electrodes and the top electrodes of the ferroelectric capacitors to be used as the material forming the bottom electrodes and the top electrodes of the ferroelectric capacitors.

According to one aspect of the present invention, there is provided a semiconductor device comprising a first electrode, a ferroelectric film formed above the first electrode, and a second electrode formed above the ferroelectric film, further comprising an intermediate layer of perovskite crystal structure formed at least one of boundary between the first electrode and the ferroelectric film, and boundary between the ferroelectric film and the second electrode. The intermediate layers having perovskite crystal structure are formed between the first electrode and the ferroelectric film and between the ferroelectric film and the second electrode, whereby even in a case that base metal is used as a material of the bottom electrode and the top electrode of a ferroelectric capacitor, the ferroelectric film can have crystal structure exhibiting ferroelectricity. Base metal can be used as a material of the bottom electrode and the top electrode of the ferroelectric capacitor, which decreases costs of semiconductor devices. Materials which have been difficult to use as materials of the bottom electrode and the top electrode of a ferroelectric capacitor can be used, whereby fabrication processes can be simplified, and electric characteristics can be improved.

According to another aspect of the present invention, there is provided a semiconductor device comprising a capacitor including a first electrode, a ferroelectric film formed above the first electrode, and a second electrode formed above the ferroelectric film; and a transistor connected to the first electrode or the second electrode, further comprising an intermediate layer of perovskite crystal structure formed at least one of boundary between the first electrode and the ferroelectric film, and boundary between the ferroelectric film and the second electrode. The intermediate layers having perovskite crystal structure are formed between the first electrode and the ferroelectric film and between the ferroelectric film and the second electrode, whereby even in a case that base metal is used as a material of the bottom electrode and the top electrode of a ferroelectric capacitor, the ferroelectric film can have crystal structure exhibiting ferroelectricity. Base metal can be used as a material of the bottom electrode and the top electrode of the ferroelectric capacitor, which decreases costs of semiconductor devices. Materials which have been difficult to use as materials of the bottom electrode and the top electrode of a ferroelectric capacitor can be used, whereby fabrication processes can be simplified, and electric characteristics can be improved.

According to farther another aspect of the present invention, there is provided a method for fabricating a semiconductor device comprising the step of forming a first electrode, the step of forming a ferroelectric film above the first electrode, and the step of forming a second electrode above the ferroelectric film, further comprising the step of forming an intermediate layer which is carystallizable into perovskite structure after the step of forming the first electrode and before the step of forming the ferroelectric film and/or after the step of forming the ferroelectric film and before the step of forming the second electrode. The intermediate layers having perovskite crystal structure are formed between the first electrode and the ferroelectric film and between the ferroelectric film and the second electrode, whereby even in a case that base metal is used as a material of the bottom electrode and the top electrode of a ferroelectric capacitor, the ferroelectric film can have crystal structure exhibiting ferroelectricity. Base metal can be used as a material of the bottom electrode and the top electrode of the ferroelectric capacitor, which decreases costs of semiconductor devices. Materials which have been difficult to use as materials of the bottom electrode and the top electrode of a ferroelectric capacitor can be used, whereby fabrication processes can be simplified, and electric characteristics can be improved.

As described above, according to the present invention, intermediate layers are each formed between the bottom electrode and the ferroelectric film and between the ferroelectric film and the top electrode. The intermediate layer is formed of a material which, even in a case that the intermediate layer is formed on the bottom electrode of a material of weak self-orientation, the intermediate layer can be crystallized in perovskite structure, and which, even in a case that a material of the bottom electrode and the top electrode is base metal, can prevent oxidation of the bottom electrode and the top electrode, and furthermore can depress transition of elements in the ferroelectric film into the bottom electrode and the top electrode. Accordingly, the intermediate layers allow the ferroelectric film to have crystal structure exhibiting ferroelectricity even in a case that materials of weak self-orientation, such as base metal, are used as materials of the bottom electrode and the top electrode of a ferroelectric capacitor. According to the present invention, inexpensive base metal, etc. can be used as materials of the bottom electrode and the top electrode of a ferroelectric capacitor, whereby semiconductor devices can have low costs.

According to the present invention, materials which have been difficult to be used as materials of the bottom electrode and the top electrode of a ferroelectric capacitor can be used, whereby fabrication processes can be further simplified, and electric characteristics can be improved.

### BRIEF DESCRIPTION OF THE DRAWINGS

FIGS. 1A and 1B are sectional views of the semiconductor device according to a first embodiment of the present invention.

FIGS. 2A to 2C are sectional views of the semiconductor device according to the first embodiment of the present invention in the steps of the method for fabricating the semiconductor device, which show the method (Part 1).

FIGS. 3A and 3B are sectional views of the semiconductor device according to the first embodiment of the present invention in the steps of the method for fabricating the semiconductor device, which show the method (Part 2).

FIGS. 4A and 4B are sectional views of the semiconductor device according to the first embodiment of the present invention in the steps of the method for fabricating the semiconductor device, which show the method (Part 3).

FIG. 5 is sectional views of the semiconductor device according to the first embodiment of the present invention in the steps of the method for fabricating the semiconductor device, which show the method (Part 4).

FIGS. 6A to 6C are sectional views of the semiconductor device according to modifications of the first embodiment of the present invention.

FIGS. 7A to 7C are sectional views of the semiconductor device according to modifications of the first embodiment of the present invention.

FIGS. 8A and 8B are sectional views of the semiconductor device according to a second embodiment of the present invention.

FIGS. 9A and 9B are sectional views of the semiconductor device according to the second embodiment of the present invention in the steps of the method for fabricating the semiconductor device, which show the method.

FIGS. 10A and 10B are sectional views of the semiconductor device according to a third embodiment of the present invention.

FIGS. 11A and 11B are sectional views of the semiconductor device according to the third embodiment in the steps of the method for fabricating the semiconductor device, which show the method.

FIGS. 12A and 12B are sectional views of the semiconductor device according to modifications of the third embodiment of the present invention.

FIG. 13 is a conceptual view of a capacitor of the conventional FRAM.

### DETAILED DESCRIPTION OF THE INVENTION

[A First Embodiment]

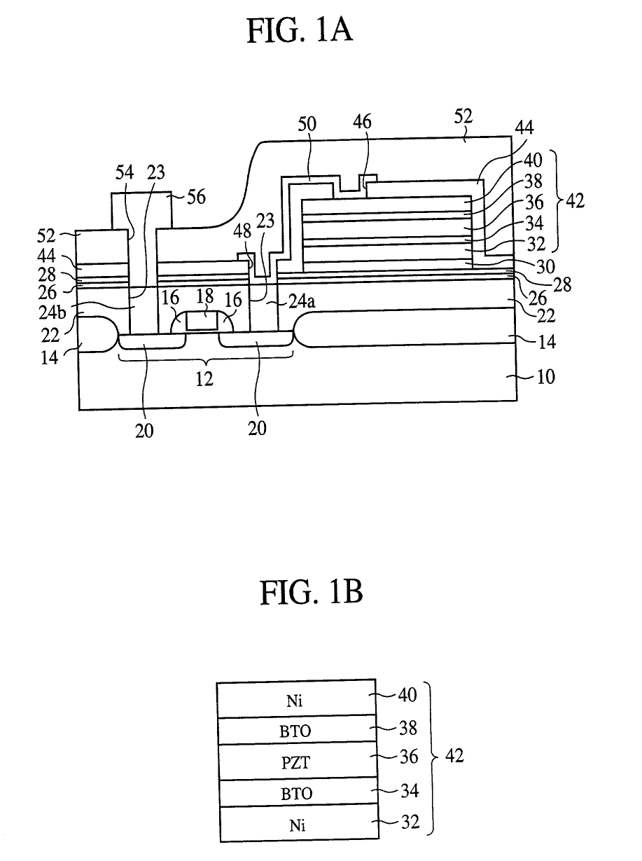

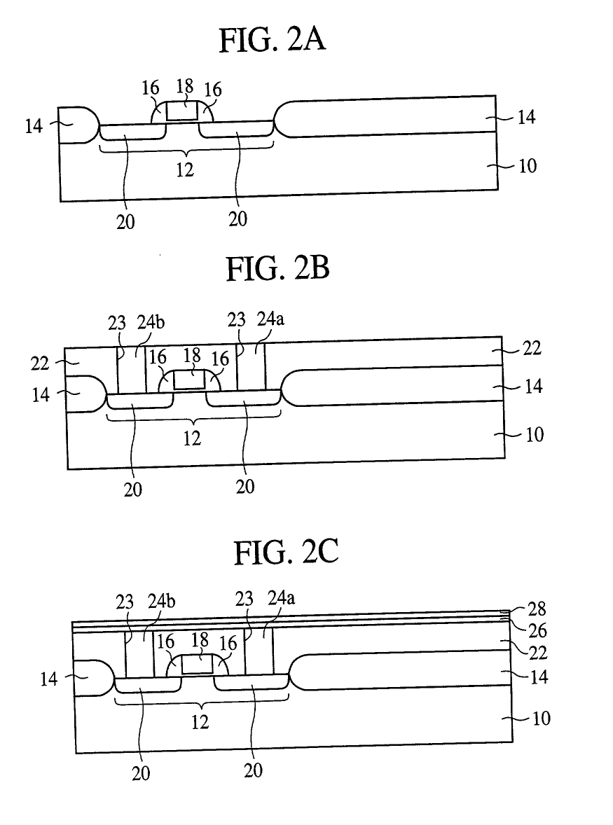

The semiconductor device according to a first embodiment of the present invention and the method for fabricating the same will be explained with reference to FIGS. 1A to 5. FIGS. 1A and 1B are sectional views of the semiconductor device according to the present embodiment. FIG. 1A is a sectional view of the semiconductor device according to the present embodiment, which shows a constitution of the semiconductor device. FIG. 1B is a sectional view of the capacitors of the semiconductor device according to the present embodiment, which shows a constitution of the capacitors. FIGS. 2A to 5 are sectional views of the semiconductor device according to the present embodiment in the steps of the method for fabricating the semiconductor device, which show the method.

(Semiconductor Device)

The semiconductor device according to the present embodiment will be explained with reference to FIGS. 1A and 1B.

As shown in FIGS. 1A and 1B, an element isolation film 14 for defining element regions 12 is formed on a silicon substrate 10. In the element regions 12 defined by the element isolation film 14, transistors including gate electrodes 18 having a sidewall insulation film 16 formed on the side walls and a source/drain diffused layer 20 are formed.

Furthermore, an inter-layer insulation film 22 of a 600 nm-thickness silicon oxide film is formed on the entire surface. Contact holes 23 are formed in the inter-layer insulation film 22 down to the source/drain diffused layer 20. Conductor plugs 24a, 24b are formed in the contact holes 23.

A stopper film 26 of a 100 nm-thickness silicon oxide nitride film is formed on the inter-layer insulation film 22. A 250 nm-thickness silicon oxide film 28 is formed on the stopper film 26.

An adhesion layer 30 of a 200 nm-thickness TiN film is formed on the silicon oxide film 28. A bottom electrode 32 of a 100 nm-thickness Ni film is formed on the adhesion layer 30.

An intermediate layer 34 of a 20 nm-thickness BTO (BaTiO₃) film is formed on the bottom electrode 32. BTO is a dielectric having perovskite crystal structure.

A ferroelectric film 36 of a 200 nm-thickness PZT (PbZr_{X}Ti_{1-X}O₃) film is formed on the intermediate layer 34. PZT is a Pb-containing oxide ferroelectric having perovskite crystal structure, i.e., a lead-based oxide ferroelectric.

An intermediate layer 38 of a 20 nm-thickness BTO film is formed on the ferroelectric film 36. An top electrode 40 of a 80 nm-thickness Ni film is formed on the intermediate layer 38.

The bottom electrode 32, the intermediate layer 34, the ferroelectric film 36, the intermediate layer 38 and the top electrode 40 constitute a capacitor 42 for a memory.

A silicon oxide film 44 of a 300 nm-thickness film is formed on the entire surface. Contact holes 46 which reaches the top electrode 40, and a contact hole 48 which reaches the conductor plug 24a are formed in the silicon oxide film 44.

An interconnection layer 50 interconnecting the top electrode 40 and the conductor plug 24a via the contact holes 46, 48 is formed on the silicon oxide film 44.

An inter-layer insulation film 52 of a 300 nm-thickness silicon oxide film is formed on the entire surface. A contact hole 54 which reaches the conductor plug 24b is formed in the inter-layer insulation film 52, the silicon oxide films 44, 28 and the stopper film 26.

A bit line 56 is formed on the inter-layer insulation film 52, connected to the conductor plug 24b via the contact hole 54. Thus, the semiconductor device according to the present embodiment is constituted.

The semiconductor device according to the present embodiment is characterized mainly in that the bottom electrode 32 and the top electrode 40 are formed of Ni, a base metal, and the intermediate layers 34, 38 each of BTO are formed respectively between the bottom electrode 32 and the ferroelectric film 36 and between the ferroelectric film 36 and the top electrode 40. Here, base metal is a term opposed to noble metal, and generally means metals which are not chemically stable, tend to be oxidized by heating in air and have high ionization tendency.

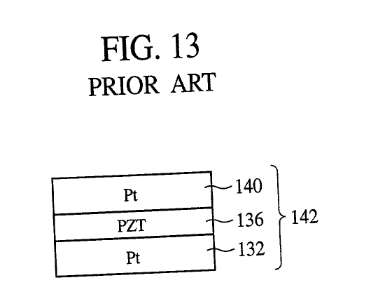

Pt, Ir, etc. are materials which tend to be self-oriented, and in a case that the bottom electrode and the top electrode are formed of such material, crystal directions of the surfaces of the bottom electrode and the top electrode can be easily aligned. Accordingly, in the case that the bottom electrode and the top electrode are formed of Pt, Ir or others, crystal directions of the ferroelectric film can be easily aligned, which makes it possible that the ferroelectric film exhibits good ferroelectricity and has perovskite crystal structure. Pt, Ir, etc. have a property that they are not easily oxidized by thermal processing even at high temperatures. Accordingly, Pt. Ir, etc. have been used as materials of the bottom electrodes 132 and the top electrodes 140 of the capacitors as shown in FIG. 13.

In contrast to this, base metals, such as Ni, etc., are materials which are not easily self-aligned, and in a case that the bottom electrode and the top electrode are formed of such material, crystal directions of the surfaces of the bottom electrode and the top electrode are not easily aligned. Accordingly, in the case that the bottom electrode and the top electrode are formed of base metals, a such as Ni or others, the ferroelectric film cannot have crystal directions easily aligned, and has found it difficult to have good perovskite crystal structure.

Furthermore, Pb and oxygen in a PZT film tend to be diffused in base metals. Accordingly, in a case that base metals, such as Ni, etc., are used as materials of the bottom electrode and the top electrode, the thermal processing, etc. for crystallizing the PZT film diffuses Pb and oxygen in the PZT film into the bottom electrode and the top electrode to resultantly cause defects of Pb and oxygen in the PZT film. When defects of Pb and oxygen are caused in PZT film, the PZT film is not easily crystallized into perovskite structure. Accordingly, good ferroelectric film cannot be obtained. In view of this it has been difficult to use base metals, such as Ni, etc., as materials of the bottom electrode and the top electrode of a ferroelectric capacitor.

Furthermore, in the case that base metals, such as Ni, etc., are used as materials of the bottom electrode and the top electrode, the bottom electrode and the top electrode are oxidized by oxygen in the PZT film. In view of this, it has been difficult to use base metals, such as Ni, etc., as materials of the bottom electrode and the top electrode of the ferroelectric capacitor.

As described above, conventionally Pt, Ir, etc., which are expensive noble metals, have been unavoidably used, which has been a barrier to cost reduction of semiconductor devices. Materials which can be used as materials of the bottom electrode and the top electrode of the ferroelectric 1capacitor have been narrowly limited to Pt, Ir, etc., which has been a barrier to simplification of fabrication processes and further improvement of electric characteristics.

Then, the present embodiment solves these problems by forming the intermediate layers 34, 38 of BTO having the following characteristics between the bottom electrode 32 and the ferroelectric film 36 and between the ferroelectric film 36 and the top electrode 40.

The Curie temperature of BTO film is not sufficiently high. It is difficult to use BTO film alone as the ferroelectric film to form the ferroelectric capacitor having good temperature characteristics. On the other hand, BTO film has a characteristic that even in a case that BTO film is formed directly on the bottom electrode of a base metal, such as Ni or others, the BTO film can form perovskite crystals by thermal processing in an inert atmosphere.

Furthermore, BTO film has a characteristic of being able to depress diffusion of Pb and oxygen in the PZT film into the bottom electrode or the top electrode of base metals, such as Ni, etc. Accordingly, the intermediate layers of BTO are formed respectively between the bottom electrode and the PZT film and between the PZT film and the top electrode to thereby prevent the PZT film from losing the ferroelectricity and also prevent the bottom electrode and the top electrode from being oxidized.

As described above, according to the present embodiment, the intermediate layers of BTO having the above-described characteristics are formed respectively between the bottom electrode and the ferroelectric film and between the ferroelectric film and the top electrode, whereby even in a case that base metals, such as Ni, etc., are used as materials of the bottom electrode and the top electrode, ferroelectric films exhibiting ferroelectricity and perovskite crystal structure can be formed. According to the present embodiment, the bottom electrode and the top electrode of the ferroelectric capacitor can be formed of base metals, such as Ni, etc., whereby the semiconductor device can have low costs.

According to the present embodiment, base metals, such as Ni, etc., which have been difficult to use, are used materials of the bottom electrode and the top electrode, whereby the fabrication process can be simplified, and electric characteristics can be improved.

(Method for Fabricating the Semiconductor Device)

Next, the method for fabricating the semiconductor device according to the present embodiment will be explained with reference to FIGS. 2A to 5.

First, as shown in FIG. 2A, the element isolation film 14 is formed on the surface of a silicon substrate 10 by LOCOS (LOCal Oxidation of Silicon) to define element regions 12.

Then, transistors each including a gate electrode 18 with a sidewall insulation film 16 formed on the side wall, and a source/drain diffused layer 20 is formed in the element regions 12.

Then, as shown in FIG. 2B, the 600 nm-thickness inter-layer insulation film 22 of a silicon oxide film is formed on the entire surface by CVD (Chemical Vapor Deposition), and the surface of the inter-layer insulation film 22 is planarized by CMP (Chemical Mechanical Polishing).

Then, contact holes 23 are formed through the inter-layer insulation film 22 down to the source/drain diffused layer 20 by photolithography.

Next, a 20 nm-thickness Ti film and a 50 nm-thickness TiN film are sequentially on the entire surface by sputtering to form an adhesion layer (not shown) of the Ti film and the TiN film. Next, a 600 nm-thickness tungsten layer (not shown) is formed on the entire surface by CVD. Thus, the adhesion layer and the tungsten layer are formed on the inter-layer insulation film 22 and in the contact holes 23.

Then, the tungsten layer and the adhesion layer are polished until the surface of the inter-layer insulation film 22 is exposed by CMP to form the conductor plugs 24a, 24b of the adhesion layer and the tungsten layer buried in the contact holes 23.

As shown in FIG. 2C, the stopper film 26 of a 100 nm-thickness silicon oxide nitride film is formed on the entire surface by CVD.

Then, the 250 nm-thickness silicon oxide film 28 is formed on the entire surface.

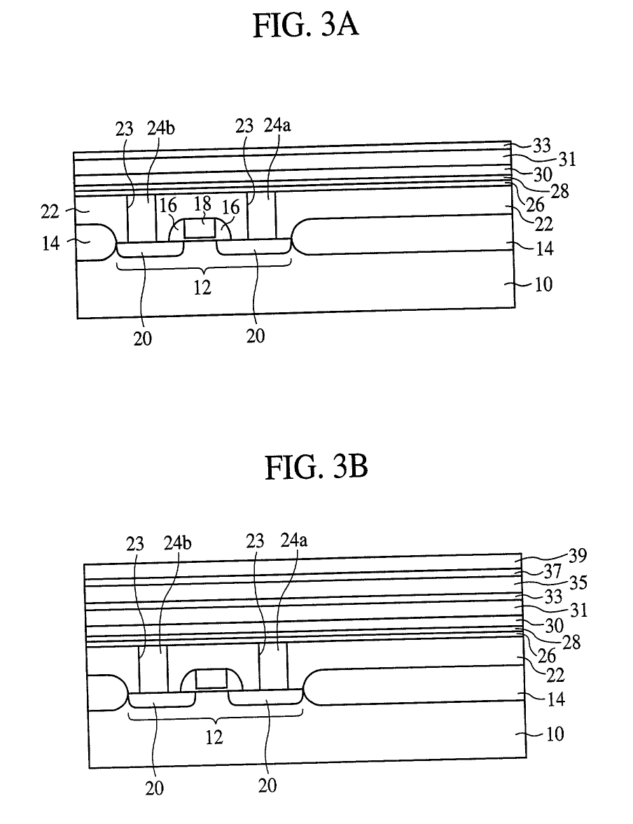

Then, as shown in FIG. 3A, the adhesion layer 30 of a 200 nm-thickness TiN film is formed on the entire surface by sputtering.

Next, a 100 nm-thickness Ni film 31 for forming the bottom electrode 32 is formed in an inert atmosphere by sputtering using argon ion beams.

Then, the 20 nm-thickness BTO (BaTiO₃) film for forming the intermediate layer 34 is formed on the entire surface in an inert atmosphere without exposure to ambient atmosphere by sputtering using argon ion beams. Film forming conditions can be, e.g., 10 sccm Ar gas flow rate, 3 Pa vacuum degree, 1.5 W applied electric power, 20 second-sputtering time, and 20 to 200° C. film forming temperature. The BTO film 33 is formed in an inert atmosphere for the purposes of preventing oxidation of the bottom electrode of Ni and forming the BT0 film of a required composition. Sputtering gives the target high transient stability, and the BTO film 33 can be formed with a required composition stabilized.

The BTO film 33 is formed continuously without exposure to ambient atmosphere after the Ni film 31 has been formed, so that the surface of the Ni film 31 is not contaminated, and no natural oxide film is formed on the surface of the Ni film 31. In a case where exposure to ambient atmosphere is performed after the step of forming the Ni film 31 and before forming the BTO film 33, the step of cleaning the surface of the Ni film 31 is necessary. However, in a case where the BTO film 33 is formed, without exposure to ambient atmosphere, continuously after the Ni film 31 has been formed, the step of cleaning the surface of the Ni film 31 is unnecessary. Accordingly, the Ni film 31 is formed, and then the BTO film 33 is formed continuously without exposure to ambient atmosphere, whereby the fabrication process can be simplified, which leads to lower fabrication costs. For forming the BTO film 33 after the Ni film 31 has been formed, continuously without exposure to ambient atmosphere, a cluster tool may be used.

The BTO film 33 may be formed by sol-gel process. Sol-gel process is a wet film-forming-method using an organic metal solution as a raw material. Sol-gel process allows a mixing ratio of the raw materials to be suitably changed, and a composition of the BTO film can be finely adjusted.

However, when the BTO film 33 is formed sol-gel process, the cluster tool cannot be used. Accordingly it is difficult to form the BTO film 33 after the Ni film 31 has been formed, without exposure to ambient atmosphere. When the BTO film 33 is formed by sol-gel process, the step of cleaning the surface of the Ni film 31 before forming the BTO film 33 is necessary.

Next, as shown in FIG. 3B, a 200 nm-thickness PZT (PbZr_{X}Ti_{1-X}O₃) film 35 for forming the ferroelectric film 36 is formed on the entire surface without exposure to ambient atmosphere by sputtering using argon ion beams. Film forming conditions can be, e.g., 100 sccm Ar gas flow rate, 3 Pa vacuum degree, 2 kW applied electric power, 5 minute sputtering time, and 20 to 200° C. film forming temperature. The PZT film 35 is formed in an inert atmosphere for the purposes of preventing a composition of the BTO film from changing and forming the PZT film of a required composition. The PZT film 35 is formed continuously without exposure to ambient atmosphere after the BTO film 33 has been formed for the prevention of contamination, etc. of the surface of the BTO film 33.

PZT film 35 is formed on the BTO film 33 which has not been crystallized in perovskite structure, which causes no special problem, because the BTO film 33, the PZT film 35, etc. can be crystallized together into perovskite structure by the thermal processing which will be described later.

The PZT 35 may be formed by sol-gel process. When the PZT film 35 is formed by sol-gel process, it is difficult to form the PZT film 35 continuously after the BTO film 33 has been formed, without esposure to ambient atmosphere.

Next, a 20 nm-thickness BTO film 37 for forming the intermediate layer 38 is formed on the entire surface in an inert atmosphere without exposure to ambient atmosphere by sputtering using argon ion beams. The BTO film 37 can be formed under, e.g., the same conditions for forming the BTO film 33.

The BTO film 37 is formed continuously after the ferroelectric film 36 has been formed, without exposure to ambient atmosphere, for the prevention of contamination, etc. of the surface of the ferroelectric film 36.

The BTO film 37 can be formed by sol-gel process, as is the BTO film 33. However, in a case where the BTO film 37 is formed by sol-gel process, it is difficult to form the BTO film 37 continuously after the ferroelectric film 35 has been formed, without exposure to ambient atmosphere.

Then, a 80 nm-thickness Ni film 39 for forming the top electrode 40 is formed on the entire surface in an inert atmosphere without exposure to ambient atmosphere by sputtering using argon ion beams.

The Ni film 39 is formed continuously after the BTO film 37 has been formed, without exposure to ambient atmosphere, so as to prevent the surface of the BTO film 37 from being contaminated.

Next, 10 minute-thermal processing of 600° C. is repeated three times in an inert atmosphere. An inert atmosphere can be, e.g., Ar gas. This thermal processing crystallizes the BTO film 33, the PZT film 35 and the BTO film 37 into perovskite structure. The thermal processing is made in an inert atmosphere for the purpose of preventing, for good perovskite structure crystallization, compositions of the BTO film 33, the PZT film 35, the BTO film 37, etc. from changing.

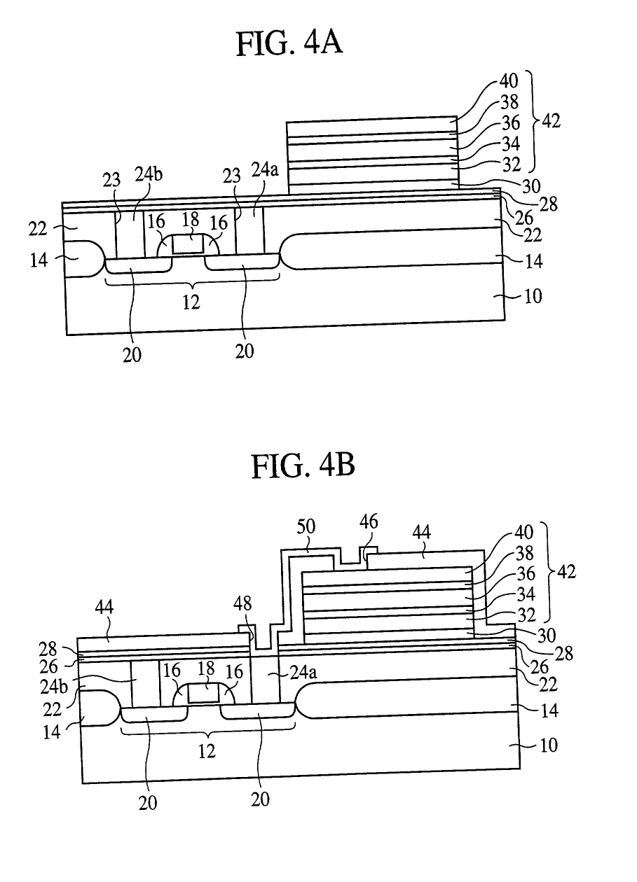

Then, as shown in FIG. 4A, the Ni film 39, the BTO film 37, the PZT film 35, the BTO film 33, the Ni film 31 and the adhesion layer 30 are patterned by using photolithography and dry etching. Thus, the capacitor 42 is formed of the bottom electrode 32 of the Ni film 31, the intermediate layer 34 of the BTO film 33, the ferroelectric film 36 of the PZT film 35, the intermediate layer 38 of the BTO film 37 and the top electrode 40 of the Ni film 39.

Then, as shown in FIG. 4B, a 300 nm-thickness silicon oxide film 44 is formed on the entire surface.

Then the contact hole 46 is formed in the silicon oxide film 44 down to the top electrode 40 by photolithography, and contact hole 48 is formed in the silicon oxide films 44, 28 and the stopper film 26 down to the conductor plug 24a.

Next, a TiN film is formed on the entire surface. Then, the TiN film is patterned by photolithograpy to form the interconnection layer 50 interconnecting the top electrode 40 and the conductor plug 24a via the contact holes 46, 48.

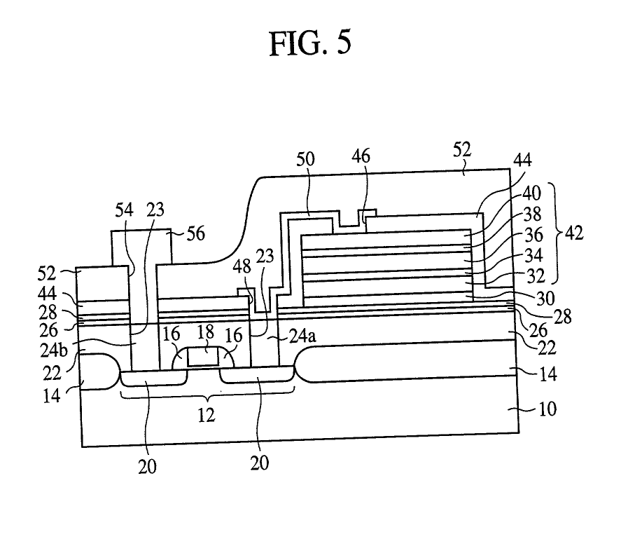

Then, as shown in FIG. 5, the inter-layer insulation film 52 of a 300 nm-thickness silicon oxide film is formed on the entire surface.

Then, a contact hole 54 is formed in the inter-layer insulation film 52, the silicon oxide films 44, 28 and the stopper film 26 down to the upper surface of the conductor plug 24b by photolithography.

Then, a 600 nm-thickness Al film is formed on the entire surface. Then, the Al film is patterned by photolithography to form the bit line 56 connected to the conductor plug 24b via the contact hole 54.

Thus, the semiconductor device according to the present embodiment is fabricated.

(Modifications of the Method for Fabricating the Semiconductor Device)

Then, modifications of the method for fabricating the semiconductor device according to the present embodiment will be explained with reference to FIGS. 2A to 5.

The semiconductor fabrication method according to the present modification is characterized in that the thermal processing for crystallizing the BTO film 33 in perovskite structure when the BTO film 33 has been formed, and after the PZT film 35, the BT0 film 37 and the Ni film 39 have been formed, the thermal processing for crystallizing the PZT film 35 and the BTO film 37 is made.

The fabrication steps up to the step of forming the BTO film 33 including the BTO film 33 forming step are the same as those of the semiconductor device fabrication method which has been explained above with reference to FIGS. 2A to 3A, and their explanation is not repeated.

Then, 10 minute-thermal processing of 600° C. is repeated three times in an inert atmosphere. An inert atmosphere can be, e.g., Ar gas (see FIG. 3A).

Then, in the same way as in the semiconductor device fabrication method explained above with reference to FIG. 3B, the PZT film 35, the BT0 film 37 and the Ni film 39 are sequentially formed.

Then, 5 minute-thermal processing of 600° C. is repeated three times in an inert atmosphere. An inert atmosphere can be, e.g., Ar gas.

The fabrication steps of the semiconductor device fabrication method according to the present modification are the same as those of the semiconductor device fabrication method explained above with reference to FIGS. 4A to 5, and their explanation is not repeated.

Thus, the semiconductor device according to the present embodiment is fabricated by the semiconductor device fabrication method according to the present modification (see FIG. 5).

As described above, the semiconductor device shown in FIGS. 1A and 1B can be fabricated by conducting, when the BTO film 33 has been formed, the thermal processing to crystallize the BTO film 33 into perovskite structure and furthermore, by conducting, when the PZT film 35, the BTO film 37 and the Ni film 39 have been formed, the thermal processing to crystallize the PZT film 35 and the BTO film 37 into perovskite structure.

(Modification (Part 1) of the Semiconductor Device)

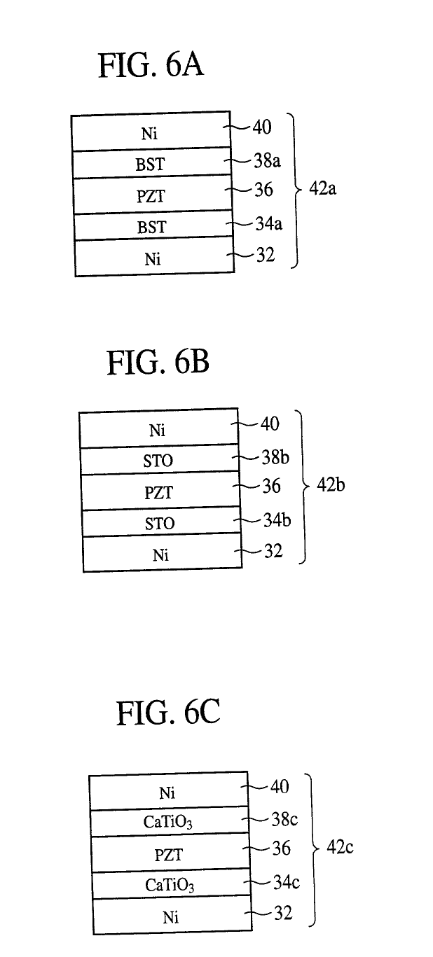

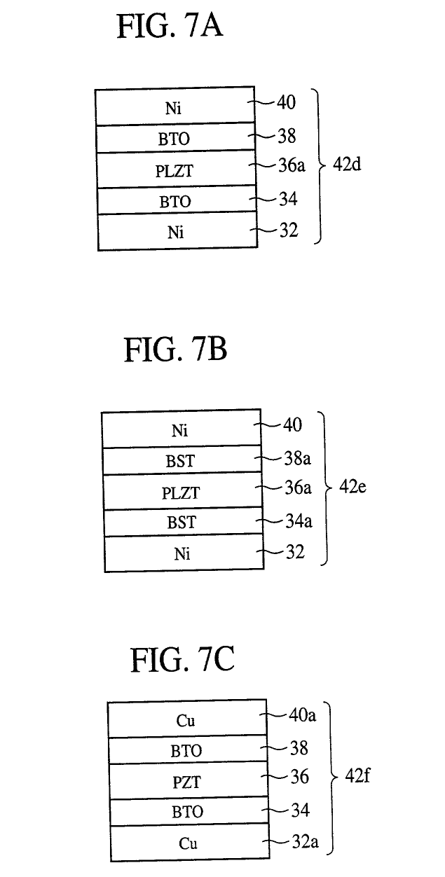

Next, modification (Part 1) of the semiconductor device according to the present embodiment will be explained with reference to FIG. 6A. FIG. 6A is a sectional view of the semiconductor device according to the present modification. In FIGS. 6A to 7C, the constituent members except a capacitor are omitted.

The capacitor 42a is characterized mainly in that an intermediate layer 34a and an intermediate layer 38a are formed of BST (Ba_{X}Sr_{1-X}TiO₃).

BST film has the above-described characteristics as BTO (BaTiO₃) film. It is difficult to form a ferroelectric capacitor having good temperature characteristics by using only BST film, whose Curie temperature is not sufficiently high. On the other hand, BST film has the characteristic that even in a case that BST film is formed directly on the bottom electrode of a base metal, such as Ni or others, whose self-orientation is weak, the BST film can be crystallized into perovskite structure by thermal processing. BST film as well BTO film has the characteristic of being able to depress diffusion of Pb and oxygen in the PZT film into the bottom electrode and the top electrode of base metals, such as Ni, etc.

Thus, as in the present modification, even in a case that BST is used as materials of the intermediate layers, a ferroelectric capacitor using base metals as materials of the bottom electrode and the top electrode can be formed.

(Modification (Part 2) of the Semiconductor Device)

Then, modification (Part 2) of the semiconductor device according to the present embodiment will be explained with reference to FIG. 6B. FIG. 6B is a sectional view of the semiconductor device according to the present modification.

The capacitor 42b shown in FIG. 6B is characterized mainly in that STO (SrTiO₃) is used as a material of intermediate layers 34b, 38b.

STO film as well as BTO film has the above-described characteristics.

Accordingly, even in a case that STO film is used as a material of the intermediate layers as in the present modification, a ferroelectric capacitor using base metals as materials of the bottom electrode and the top electrode can be formed.

(Modification (Part 3) of the Semiconductor Device)

Modification (Part 3) of the semiconductor device according to the present embodiment will be explained with reference to FIG. 6C. FIG. 6C is a sectional view of the semiconductor device according to the present modification.

The capacitor 42c shown in FIG. 6C is characterized mainly in that CaTiO₃ film is used as a material of intermediate layers 34c, 38c.

CaTiO₃ film as well as BTO film has the above-described characteristics.

Accordingly, even in a case that CaTiO₃ film is used as a material of the intermediate layers as in the present modification, a ferroelectric capacitor using base metals as materials of the bottom electrode and the top electrode can be formed.

(Modification (Part 4) of the Semiconductor Device)

Then, modification (Part 4) of the semiconductor device according to the present embodiment will be explained with reference to FIG. 7A. FIG. 7A is a sectional view of the semiconductor device according to the present modification.

The capacitor 42d shown in FIG. 7A is characterized mainly in that PLZT ((Pb_{1-Y}La_{Y})(Zr_{1-X}Ti_{X})O₃), which is PZT with La added, is used as a material of the ferroelectric film.

PLZT film as well as PZT film is a lead-based oxide ferroelectric film having perovskite crystal structure, which exhibits ferroelectricity.

In the present modification, PLZT is used as a material of the ferroelectric film for the purpose of depressing depletion of oxygen from the ferroelectric film when the thermal processing is made in a hydrogen atmosphere.

In the general semiconductor fabrication process, thermal processing is often made in hydrogen atmosphere. Accordingly, in a case that PZT film is used as the ferroelectric film, oxygen is depleted from the PZT film by the thermal processing in hydrogen atmosphere because oxygen in the PZT film tends to bond with hydrogen, and depletion of oxygen in the PZT film often takes place. When oxygen depletion takes place in the PZT film, good perovskite crystal structure cannot be formed, and the capacitor can not exhibit good ferroelectricity.

In the case that PLZT is used as a material of a ferroelectric film as in the present modification, the added La can depress oxygen from depleting from the PLZT film. Accordingly, even when thermal processing is made in hydrogen atmosphere, good perovskite crystal structure can be retained, and the capacitor can exhibit good ferroelectricity.

The PLZT film may have composition ratios of, for example, X=0.6 and Y=0.01. Composition ratios of the PLZT film are not limited to the composition ratios, and can be set suitably to form a ferroelectric capacitor of required characteristics.

As described above, in the present embodiment, PLZT film is used as the ferroelectric film. Even in a case that thermal processing is made in hydrogen atmosphere, depletion of oxygen from the PLZT film can be depressed. Accordingly, in the present modification, good perovskite crystal structure can be ensured, and a semiconductor device whose ferroelectric capacitors have good electric characteristics can be provided.

(Modification (Part 5) of the Semiconductor Device)

Next, the modification (Part 5) of the semiconductor device according to the present embodiment will be explained with reference to FIG. 7B. FIG. 7B is a sectional view of the semiconductor device according to the present modification.

The capacitor 42e shown in FIG. 7B is characterized mainly in that intermediate layers 34a, 38a are formed of BST, and PLZT is used as a material of a ferroelectric film 36a.

As described above, even in the case that the intermediate layers 34a, 38a of BST and the ferroelectric film 36a of PLZT are combined, a ferroelectric capacitor using a base metal as a material of the bottom electrode 32 and the top electrode 40 can be formed.

(Modification (Part 6) of the Semiconductor Device)

Next, modification (Part 6) of the semiconductor device according to the present embodiment will be explained with reference to FIG. 7C. FIG. 7C is a sectional view of the semiconductor device according to the present modification.

The capacitor 42f shown in FIG. 7C is characterized mainly in that Cu is used as a material of the bottom electrode 32a and the top electrode 40a.

That is, in the semiconductor device shown in FIGS. 1A and 1B, Ni is used as a material of the bottom electrode 32 and the top electrode 40, but in the present modification, Cu is used as a material of the bottom electrode 32a and the top electrode 40a. Cu, whose electric resistance is low and has high heat resistance, is a material recently much noted as an interconnection material, etc. of semiconductor devices. Accordingly, according to the present modification, it is possible that the top electrode and the bottom electrode are formed integral with the interconnection layer, etc.

As described above, materials, compositions, combinations, etc. for the intermediate layers, the ferroelectric film, the bottom electrode and the top electrode can be suitably set so that a ferroelectric capacitor having required characteristics can be formed.

[A Second Embodiment]

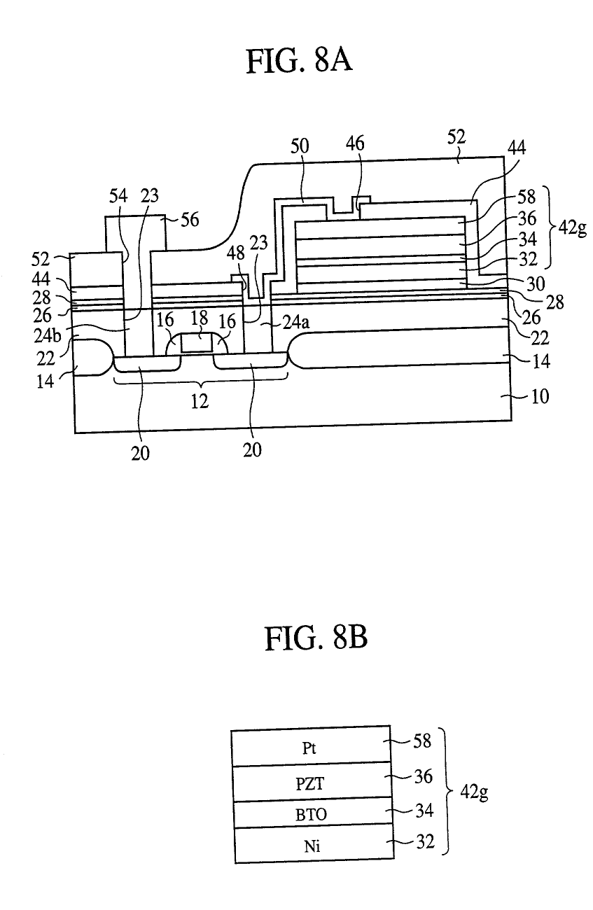

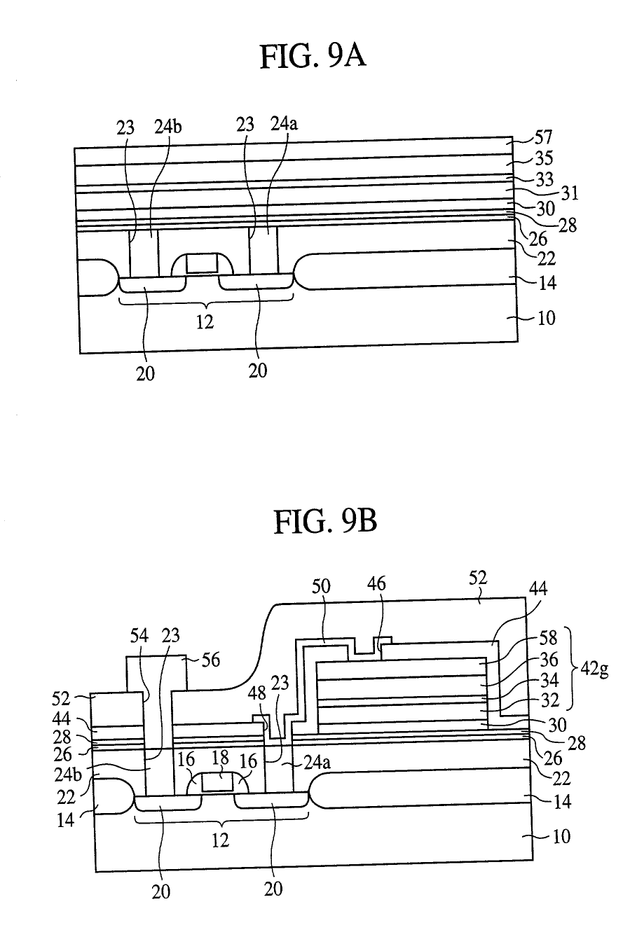

The semiconductor device according to a second embodiment of the present invention and the method for fabricating the same will be explained with reference to FIGS. 8A to 9B. FIGS. 8A and 8B are sectional views of the semiconductor device according to the present embodiment. FIG. 8A is a sectional view of the semiconductor device according to the present embodiment, which shows a structure thereof. FIG. 8B is a sectional view of a capacitor of the semiconductor device according to the present embodiment, which shows a structure thereof. FIGS. 9A and 9B are sectional views of the semiconductor device in the steps of the method for fabricating the semiconductor device according to the present embodiment, which show the method. The same member of the present embodiment as those of the semiconductor device according to the first embodiment and the method for fabricating the same are represented by the same reference numbers not to repeat or to simplify their explanation.

(Semiconductor Device)

First, the semiconductor device according to the present embodiment will be explained with reference to FIGS. 8A and 8B.

The semiconductor device according to the present embodiment is characterized mainly in that a material of the bottom electrodes is Ni, and a material of the top electrodes is Pt.

As shown in FIGS. 8A and 8B, an intermediate layer 34 of BTO is formed on a bottom electrode 32 of Ni. A ferroelectric film 36 of PZT is formed on the intermediate layer 34.

An top electrode 58 of Pt is formed on the ferroelectric film 36. In the present embodiment, a material of the top electrode 58 is Pt, which makes it unnecessary to form an intermediate layer between the ferroelectric film 36 and the top electrode 58.

The bottom electrode 32, the intermediate layer 34, the ferroelectric film 36 and the top electrode 58 constitute capacitors 42g for a memory.

In the present embodiment, Ni, which is an inexpensive base metal, is used as a material of at least the bottom electrode 32. In comparison with the semiconductor device shown in FIG. 13 in which an expensive noble metal is used as materials of both the bottom electrode and the top electrode, the semiconductor device according to the present embodiment can have lower costs.

(Method for Fabricating the Semiconductor Device)

Next, the method for fabricating the semiconductor device according to the present embodiment will be explained with reference to FIGS. 9A and 9B.

The steps up to the step of forming the BTO film 33 including the BTO film 33 forming step are the same as those of the method for fabricating the semiconductor device according to the first embodiment shown in FIGS. 2A to 3A, and their explanation is not repeated.

Then, as shown in FIG. 9A, in the same way as in the first embodiment, a 200 nm-thickness PZT film 35 is formed on the ferroelectric film 36 without exposure to ambient atmosphere.

Then, a 100 nm-thickness Pt film 57 for forming the top electrode 58 is formed on the entire surface by sputtering without exposure to ambient atmosphere.

The steps of the semiconductor device fabrication method following the above-described step are the same as those of the method for fabricating the semiconductor device according to the first embodiment shown in FIGS. 4A to 5, and their explanation is repeated.

Thus, the semiconductor device according to the present embodiment is fabricated (see FIG. 9B).

As described above, according to the present embodiment, an inexpensive base metal is used as a material of at least the bottom electrode, which makes it possible to provide a semiconductor device of lower costs than the conventional semiconductor device shown in FIG. 13, in which an expensive noble metal is used as materials of the bottom electrode and the top electrode.

[A Third Embodiment]

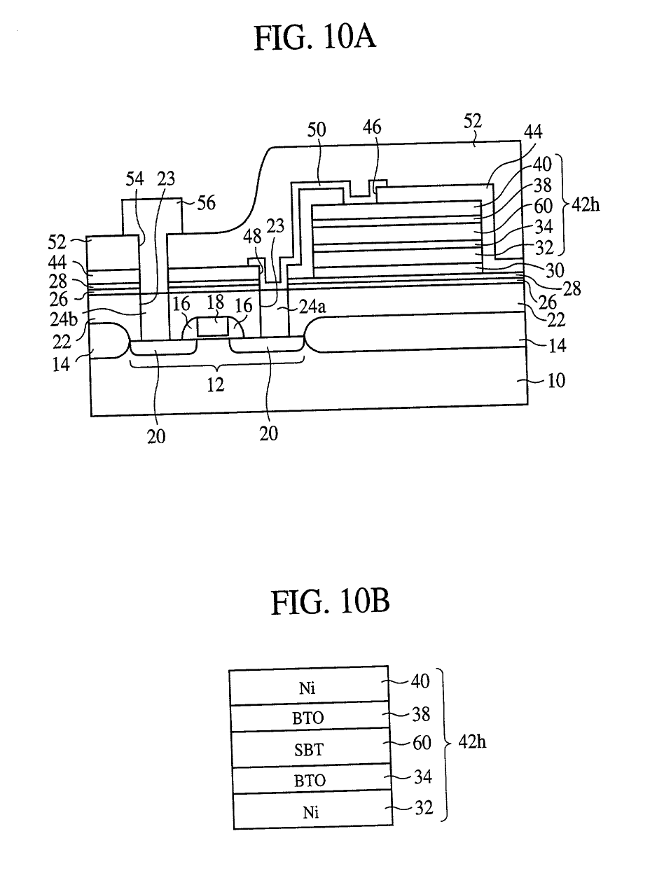

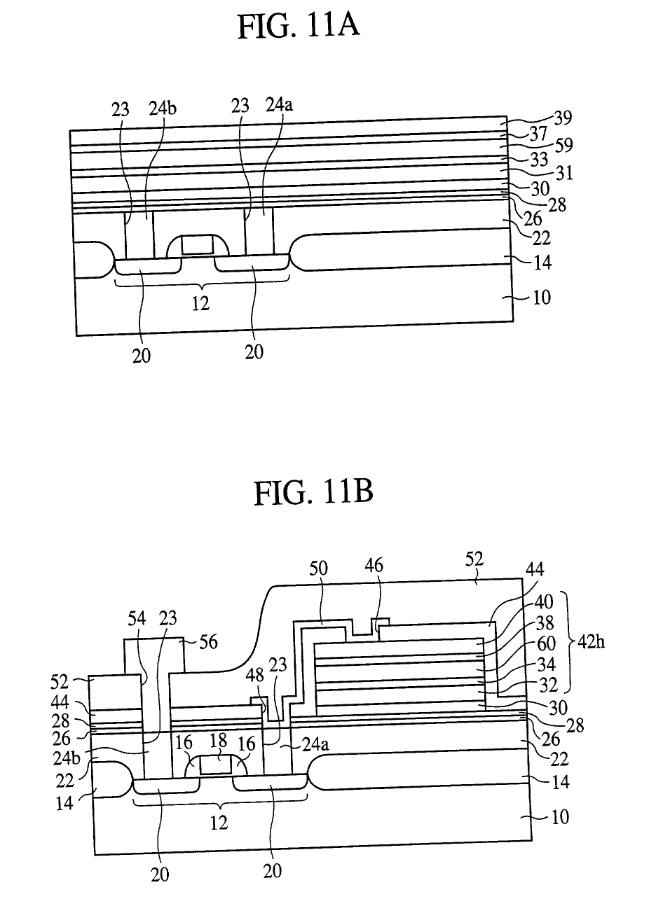

The semiconductor device according to a third embodiment of the present invention and the method for fabricating the same will be explained with reference to FIGS. 10A to 11B. FIGS. 10A and 11B are sectional views of the semiconductor device according to the present embodiment. FIG. 10A is a sectional view of the semiconductor device according to the present embodiment, which shows a structure thereof. FIG. 10B is a sectional view of a capacitor of the semiconductor device according to the present embodiment, which shows a structure of the capacitor. FIGS. 11A and 11B are sectional views of the semiconductor device according to the present embodiment in the steps of the method for fabricating the same, which show the method. The same members of the present embodiment as those of the semiconductor device according to the first or the second embodiment and the method for fabricating the same are represented by the same reference numbers not to repeat or to simplify their explanation.

(Semiconductor Device)

First the semiconductor device according to the present embodiment will be explained with reference to FIGS. 10A and 10B.

The semiconductor device shown in FIGS. 10A and 10B are characterized mainly in that a ferroelectric film 60 is provided by (AO)₂(B_{Y-1}C_{Y}O_{3Y+1}) film in which A is at least any element of Tl, Pb, Bi, or rare earth element; B is at least any element of Bi, Pb, Ca, Sr and Ba; C is at least any element of Ti, Nb, Ta, W, Mo, Fe, Co, Cr and Zr; and Y is any of 2, 3, 4 and 5.

In the first and the second embodiments, a lead-based oxide ferroelectric film, such as PZT film is used as the ferroelectric films 36, but the ferroelectric film of the present embodiment can be used without any remarkable problem. That is, even in a case that the ferroelectric film of the present embodiment is used, a crystal structure exhibiting good ferroelectricity can be formed, and a ferroelectric capacitor having good electric characteristics can be formed.

The above-described (AO)₂(B_{Y-1}C_{Y}O_{3Y+1}) film in which, for example, A is Bi, B is Sr, C is Ta, and Y is 2 is SBT(SrBi₂Ta₂O₉) film.

SBT film is a ferroelectric film having a crystal structure of perovskite structure and Bi₂O₃ laid one on the other, i.e., a bismuth layer structure ferroelectric film.

Bismuth layer structure ferroelectric film exhibits good ferroelectricity as does lead-based oxide ferroelectric film.

Bismuth layer structure ferroelectric film, such as SBT film, can provide a ferroelectric film 60 exhibiting good ferroelectricity by forming intermediate layers 34, 38 as in the embodiments where PZT film is used, even in a case that base metals, such as Ni, etc., are used as the bottom electrode 32 and the top electrode 40.

As described above, according to the present embodiment, even in the case that the above-described ferroelectric film is used, a ferroelectric capacitor using base metals as materials of the bottom electrode and top electrode.

According to the present embodiment, even in the case the above-described ferroelectric film is used, material to be used as materials of the bottom electrode and the top electrode are not narrowly limited to Pt, Ir, etc., which makes it possible to simplify the fabrication process and improve electric characteristics.

(Method for Fabricating the Semiconductor Device)

Then, the method for fabricating the semiconductor device according to the present embodiment will be explained with reference to FIGS. 11A and 11B.

The fabrication steps of the method for fabricating the semiconductor device according to the present embodiment including the step of forming the BTO film 31 are the same as those of the method for fabricating the semiconductor device according to the first embodiment shown in FIGS. 2A to 3A, and their explanation is not repeated.

Then, as shown in FIG. 11A, a 200 nm-thickness SBT film 59 for forming the ferroelectric film 60 is formed on the entire surface without exposure to ambient atmosphere by sputtering using argon ion beams. Film forming conditions are, e.g., 10 sccm Ar gas flow rate, 3 Pa vacuum degree, 2 kW applied electric power, 5 minutes sputtering and 20 to 200° C. film forming temperature.

Next, in the same way as in the first embodiment, a BTO film 37 for forming the intermediate layer 38, and an Ni film 39 for forming the top electrode 40 are sequentially formed without exposure to ambient atmosphere.

The following steps of the semiconductor fabrication method according to the present embodiment are the same as those of the method for fabricating the semiconductor device according to the first embodiment shown in FIGS. 4A to 5, and their explanation is not repeated.

Thus, the semiconductor device according to the present embodiment is fabricated (see FIG. 11B).

(Modification (Part 1))

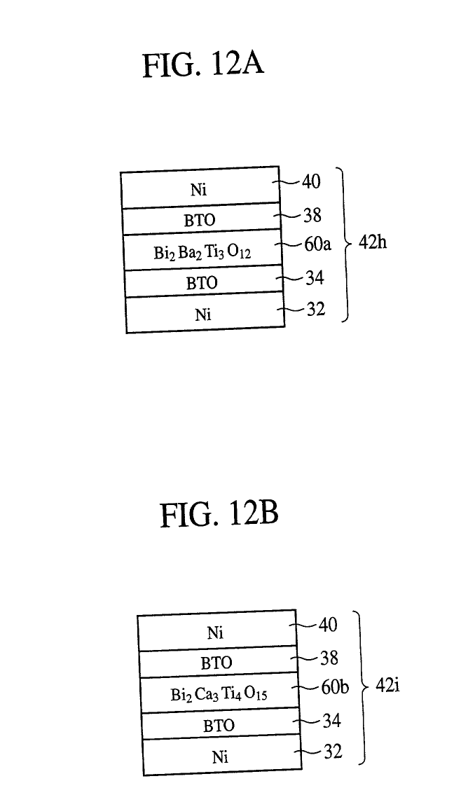

Next, modification (Part 1) of the semiconductor device according to the present embodiment will be explained with reference to FIG. 12A. FIG. 12A is a sectional view of the semiconductor device according to the present modification.

The capacitor shown in FIG. 12A is characterized mainly in that a ferroelectric film 60a is provided by the above-described (AO)₂(B_{Y-1}C_{Y}O_{3Y+1}) film in which A is Bi; B is Ba; C is Ti; and Y is 3, i.e., Bi₂Ba₂Ti₃O₁₂.

Bi₂Ba₂Ti₃O₁₂ as well as SBT film is bismuth layer structure ferroelectric film.

Thus, even in the case that Bi₂Ba₂Ti₃O₁₂ is used as a material of the ferroelecgtric film, a ferroelectric capacitor using a base metal as a material of the bottom electrode and the top electrode can be formed.

(Modification (Part 2))

Next, modification of the present embodiment will be explained with reference to FIG. 12B. FIG. 12B is a sectional view of the semiconductor device according to the present modification.

The capacitor 42i shown in FIG. 12B is characterized mainly in that a ferroelectric film 60b is provided by the above-described (AO)₂(B_{Y-1}C_{Y}O_{3Y+1}) film in which A is Bi; B is Ca; C is Ti; and Y is 4, i.e., Bi₂Ca₃Ti₄O₁₅.

Bi₂Ca₃Ti₄O₁₅ as well as SBT film is bismuth layer structure ferroelectric film.

Thus, even in the case that Bi₂Ca₃Ti₄O₁₅ film is used as a material of the ferroelectric film, a ferroelectric capacitor using a base meal as a material of the bottom electrode and the top electrode can be formed.

[Modified Embodiments]

The present invention is not limited to the above-described embodiments and can cover other various modifications.

For example, in the above-described embodiments, BTO, etc. are used as the intermediate layers, but materials of the intermediate layers are not limited to the above-described materials. Any material can be used as long as the material has the above-described characteristics, i.e., the material which can be crystallized into perovskite structure even in a case that the intermediate layers are formed on the bottom electrode of a material of weak self-orientation, can prevent the oxidation of the bottom electrode and the top electrode even in a case that the bottom electrode and the top electrode are formed of a base metal, and can depress transition of elements in the ferroelectric film to the bottom electrode and the top electrode.

Materials which can satisfy the above-described conditions are, e.g., materials formed of BTO with at least any element of Ca, Sr, Tl, Pb, Bi, rare earth element, Nb, Ta, W, Mo, Fe, Co, Cr and Zr added. Specifically, for example, Ba(Bi_{X}Nb_{Y}Ti_{1-X-Y})O₃, Ba(Bi_{X}Ta_{Y}Ti_{1-X-Y})O₃, Ba(Bi_{X}W_{Y}Ti_{1-X-Y})O₃, Ba(Bi_{X}Mo_{Y}Ti_{1-X-Y})O₃, Ba(Bi_{X}Fe_{Y}Ti_{1-X-Y})O₃, Ba(Bi_{X}Co_{Y}Ti_{1-X-Y})O₃, Ba(Bi_{X}Cr_{Y}Ti_{1-X-Y})O₃, Ba(Bi_{X}Zr_{Y}Ti_{1-X-Y})O₃, etc. can be used as the intermediate layers. These materials may have composition ratios of, for example, X=0.2 and Y=0.25.

As materials of the intermediate layers may be used (Ba_{X}Ca_{Y}Sr_{1-X-Y})TiO₃, (Ba_{X}Tl_{Y}Sr_{1-X-Y})TiO₃, etc. These materials may have composition ratios of, for example, X=0.5 and Y=0.25. (Ba_{X}Pb_{1-X})Ti0₃, etc. can be used as materials of the intermediate layers. A composition ratio of these materials can be, e.g., X=0.5. Ba_{X}(Er_{Y}Ti_{1-Y})O₃, etc. may be used as materials of the intermediate layers. These materials can have composition ratios of, for example, X=0. 5 and Y=0.5. The above-described composition ratios can be suitably adjusted so as to give the intermediate layers required characteristics.

In the present embodiment, as a material of the ferroelectric film, lead-based oxide ferroelectrics, etc. are used, but a material of the ferroelectric film is not limited to the materials described in the present embodiment. Any other ferroelectric film can be suitably used.

In the first and the second embodiments, the lead-based oxide ferroelectrics have been explained by means of PZT, etc. However, the lead-based oxide ferroelectric is not limited to the materials described in the embodiments, and any other lead-based oxide ferroelectrics can be suitably used. For example, at least any element of La, Sr and Ca may be further added to PZT. For example, PLCSZT, which is a lead-based oxide ferroelectric formed of PZT with La, Ca and Sr added, can be used.

In the above-described embodiments, materials of the bottom electrode and the top electrode are Ni and Cu, but any other base metals can be suitably used. For example, Cr, etc. can be used.

In the above-described embodiments, a material of the bottom electrode and the top electrode is Ni, but other elements may be added to Ni. For example, at least any element of Sc, Ti, V, Cr, Mo, Fe, Co, Cu, Y, Zr, Nb, Mn, Ta, W, Ir and Pt may be added to Ni.

In the above-described embodiment, Cu is also used as a material of the bottom electrode and the top electrode, but other elements may be added to Cu. For example, at least any element of Sc, Ti, V, Cr, Mo, Fe, Co, Ni, Y, Zr, Nb, Mn, Ta, W, Ir and Pt may be added to Cu.

In the above-described embodiment, base metals, such as Ni, etc., are used s materials of the bottom electrode and the top electrode for the purpose of low costs, but relatively inexpensive noble metals may be used for the cost reduction. For example, Au, etc. which is less expensive than Pt, Ir, etc., is used to thereby provide semiconductor device of lower cost than the conventional semiconductor device.

In the second embodiment, Pt is used as a material of the top electrode formed of noble metal, but a material of the top electrode of noble metal is not limited to Pt. For example, Pt alloys maybe used, or Ir, Ir alloys, etc. may be used.

In the second embodiment, the bottom electrode is formed of base metal, and the top electrode is formed of noble metal. The bottom electrode may be formed of noble metal, and the top electrode is formed of base metal, and in this case it is necessary to form an intermediate layer between the ferroelectric film and the top electrode.

In the third embodiment, bismuth layer structure ferroelectric is exemplified by BST, etc. Bismuth layer structure ferroelectric is not limited to the materials described in the third embodiment, and any other bismuth layer structure ferroelectrics can be suitably used.

In the third embodiment, A, B, C and Y are set to form bismuth layer structure ferroelectric. However, A, B, C and Y are not set so as to restrictively form bismuth layer structure ferroelectric, and may be suitably set so as to form ferroelectrics having required characteristics.

The above-described embodiments have been explained by means of FRAM. However, the present invention is not essentially applied to FRAM and is applicable to any semiconductor devices using ferroelectrics. The above-described capacitor is applicable to a single capacitor. When the above-described capacitor is applied to a single capacitor, the above-described function and effects can be provided.

In the above-described embodiments, the intermediate layers and the ferroelectric films are formed by sputtering and sol-gel process. However, the intermediate layers and the ferroelectric films may be formed not only by sputtering and sol-gel process but also by other film forming processes.

In the above-described embodiments, an inert gas used in forming the intermediate layers and the ferroelectric films is argon gas. However, not only argon gas but also any other inert gas can be used, and helium gas, neon gas, krypton gas, nitrogen gas, xenon gas, their mixed gases or others, for example, can be suitably used.

What is claimed is:

1. A semiconductor device comprising a first electrode, a ferroelectric film formed above the first electrode, and a second electrode formed above the ferroelectric film, further comprising
an intermediate layer of perovskite crystal structure formed at least one of boundary between the first electrode and the ferroelectric film, and boundary between the ferroelectric film and the second electrode.

2. A semiconductor device according to claim 1, wherein
the intermediate layer is BaTiO₃ layer, SrTiO₃ layer, or CaTiO₃ layer.

3. A semiconductor device according to claim 2 wherein
the intermediate layer further contains at least any element of Ca, Sr, Tl, Pb, Bi, rare earth element, Nb, Ta, W, Mo, Fe, Co, Cr, and Zr.

4. A semiconductor device according to claim 1, wherein
the first electrode and/or the second electrode is base metal.

5. A semiconductor device according to claim 2, wherein p1 the first electrode and/or the second electrode is base metal.

6. A semiconductor device according to claim 3, wherein
the first electrode and/or the second electrode is base metal.

7. A semiconductor device according to claim 4, wherein
the base metal is Ni, Cu or Cr.

8. A semiconductor device according to claim 5, wherein
the base metal is Ni, Cu or Cr.

9. A semiconductor device according to claim 6, wherein
the base metal is Ni, Cu or Cr.

10. A semiconductor device according to claim 1, wherein
the ferroelectric film is lead-based oxide ferroelectric film.

11. A semiconductor device according to claim 10, wherein
the lead-based oxide ferroelectric film is PbZr_{X}Ti_{1-X}O₃ film.

12. A semiconductor device according to claim 11, wherein
the PbZr_{X}Ti_{1-X}O₃ film further contains at least any element of La, Sr and Ca.

13. A semiconductor device according to claim 1, wherein
the ferroelectric film is (AO)₂(B_{Y-1}C_{Y}O_{3Y+1}) film wherein A is at least any element of Tl, Pb, Bi and rare earth element; B is at least any element of Bi, Pb, Ca, Sr and Ba; C is at least any element of Ti, Nb, Ta, W, Mo, Fe, Co, Cr and Zr; and Y is any of 2, 3, 4 and 5.

14. A semiconductor device according to claim 13, wherein
the ferroelectric film is bismuth layer structure ferroelectric film.

15. A semiconductor device according to claim 14, wherein
the bismuth layer structure ferroelectric film is SrBi₂Ta₂O₉ film, Bi₂Ba₂Ti₃O₁₂ film or Bi₂Ca₃Ti₄O₁₅ film.

16. A semiconductor device comprising a capacitor including a first electrode, a ferroelectric film formed above the first electrode, and a second electrode formed above the ferroelectric film; and a transistor connected to the first electrode or the second electrode, further comprising
an intermediate layer of perovskite crystal structure formed at least one of boundary between the first electrode and the ferroelectric film, and boundary between the ferroelectric film and the second electrode.

17. A method for fabricating a semiconductor device comprising the step of forming a first electrode, the step of forming a ferroelectric film above the first electrode, and the step of forming a second electrode above the ferroelectric film, further comprising
the step of forming an intermediate layer which is carystallizable into perovskite structure after the step of forming the first electrode and before the step of forming the ferroelectric film and/or after the step of forming the ferroelectric film and before the step of forming the second electrode.

18. A method for fabricating a semiconductor device according to claim 17, wherein
in the step of forming the intermediate layer, the intermediate layer is formed in an inert atmosphere.

19. A method for fabricating a semiconductor device according to claim 17, wherein
the intermediate layer and the ferroelectric film are formed without exposed to ambient atmosphere.
